(19) United States
(12) Patent Application Publication
(10) Pub. No.: US 2005/0066888 A1
(43) Pub. Date: Mar. 31, 2005

(54) Active dampening orbit stopper for Czochralski crystal growth

(76) Inventors: Jesse B. Griggs, Vancouver, WA (US); Robert L. Faulconer, Vancouver, WA (US)

Correspondence Address: SEH AMERICA, INC., M/S 58-1-921, 4111 N.E. 112TH AVE., VANCOUVER, WA, 98682, US

(21) Appl. No.: 10/676,274

(22) Filed: Sep. 30, 2003

(51) Int. Cl. C30B 35/00; C30B 15/00; C30B 21/06; C30B 27/02; C30B 28/10; C30B 30/04

(52) U.S. Cl. 117/217; 117/208; 117/218

(57) ABSTRACT

A Czochralski single crystal pulling apparatus having a one or more active damping modules used to reduce or eliminate unwanted orbital motion during crystal growth. The active damping module utilizes the mass of the crystal and the pendular length to determine the critical damping coefficient. A controller continually adjusts a control loop dampener to keep the active damping module at the critical dampening coefficient during crystal growth. A wire interceptor is located near the pulling wire, such that if a growing crystal experiences orbit, the pull wire will contact the wire interceptor, and the pendular energy associated with orbit will be transferred to, and absorbed by, the active damping module.

### FIELD OF THE INVENTION

This invention relates generally to Czochralski type crystal pulling machines, and more specifically to a method and apparatus for controlling pendular motion of the crystal during growth.

### BACKGROUND OF THE INVENTION

Semiconductors used in the electronics industry are typically manufactured from monocrystalline ingots, such as silicon ingots, grown by the so-called Czochralski (CZ) process. In the CZ process, a charge material such as polysilicon chunks is loaded in a crucible, which is placed inside a crystal growing machine. The charge material is then heated to bring it to a molten state and allowed to thermally stabilize throughout the molten mass. A monocrystalline seed containing the crystallographic properties desired of the ingot to be grown is attached to a cable and lowered down to be dipped into the molten mass. The seed is then slowly extracted from the melt, wherein material from the melt attaches to the bottom of the seed, matching the crystallographic properties of the seed, such that an ingot is “grown”. Under ideal conditions, the ingot grown can achieve diameters of up to 300 mm or larger. An inert purge gas, such as argon, is passed downward from the top of the machine over the melt and growing crystal, and vented out the bottom of the machine. The vent gas is used to remove reactive SiC gases created from the interaction of the molten silicon with the quartz crucible, as well as to provide a means for cooling the growing crystal and meet thermal gradient requirements. Typically the seed is rotated relative to the melt, either by rotating the seed and seed cable, the crucible containing the melt, or more often rotating both. This rotation helps improve stability of oxygen concentration and dopant concentration radially through the growing crystal, as well has help maintain the desired cylindrical shape of the growing ingot.

Under ideal conditions, the crystal is grown through an imaginary axial axis running directly downward from the point of entry of the cable or wire in the top of the machine through the center of the crystal such that the only motion of the crystal is the growth directly upward and the rotation of the crystal around its axial axis. Due to the rotation of the crucible and the growing crystal however, a phenomenon known as orbit may occur, wherein the growing ingot swings in a pendular motion while the crystal is growing. Since the crystal is growing at the interface of the ingot and the molten material, and since the ingot and molten material are rotating in opposite directions, the added angular forces added from orbit cause the ingot to grow in a non-linear fashion similar to the shape of a cork screw. Any non-linear shape is undesirable, as it reduces the amount of usable ingot and increases handling costs associated with trying to salvage sections of usable ingot.

Similarly, when orbit occurs the pendular motion inhibits accurate diameter measurements from being made, such that an ingot may be grown to a diameter larger than desired, thereby lowering productivity and costs associated with manufacturing. If a crystal ingot is grown to a diameter smaller than desired, that entire section of crystal may be discarded as scrap, again negatively impacting productivity and yields.

Attempts have been made to prevent orbit from occurring, with limited success.

For example, U.S. Pat. No. 5,089,239 teaches one or more mechanical dampening devices that surround the cable at a specified location about midway between the top of the machine and the molten mass. As orbit occurs, the cable begins to oscillate in a pendular motion and comes in contact with the mechanical dampening device. The theory of this device being contact with the cable at that location would shorten the free length of the wire, and significantly increase the natural oscillation frequency, thereby reducing orbit. Disadvantageously, however, the dampening device is removed during crystal growth as the growing crystal approaches the dampening device. Retraction of these parts has the potential for contributing contamination in the form of falling particles into the melt.

Similarly, U.S. Pat. No. 5,582,642 provides an apparatus, this time near the top of the machine, with a guide capable of being moved horizontally in at least two non-collinear directions, and a sensor, attached to a controller, to determine when the cable is not in proper alignment. The guide is moved by an actuator to dampen the oscillation of the cable. The guide is in constant contact with the cable, and again poses the problems of wear on the cable and contamination, combined with the disadvantages of a quite complex system.

### SUMMARY OF THE INVENTION

In order to overcome the drawbacks and limitations inherent with the prior art systems to limit or inhibit orbit, the present invention provides an apparatus and method to prevent or limit orbit through an active damping module. Utilizing the mass of the crystal being grown and the distance the center of gravity is from the pendular point, the characteristics of the orbiting crystal can be determined. A damping module is controlled to counter the natural frequency of the growing crystal

### BRIEF DESCRIPTION OF THE DRAWINGS

FIG. 1 is a partial sectional view of a crystal growing apparatus containing active damping modules.

FIG. 2 is a block diagram depicting a crystal growing apparatus having active dampening modules and a controller.

### DETAILED DESCRIPTION OF THE INVENTION

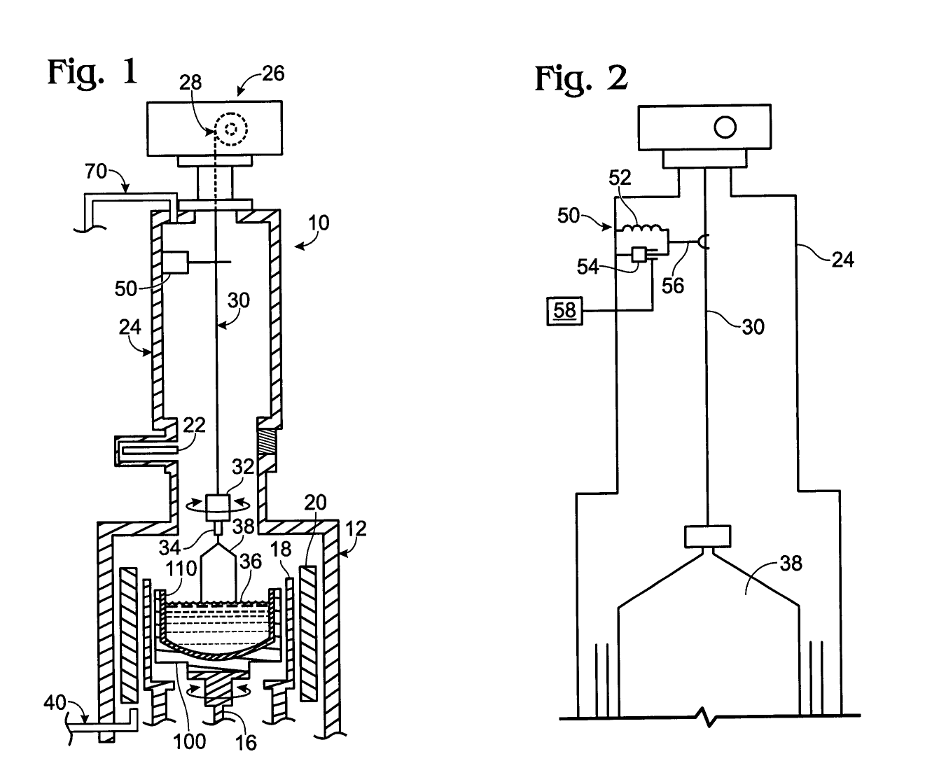

Turning now to FIG. 1, a crystal growing apparatus 10 includes a bottom chamber 12. The bottom chamber 12 houses a quartz crucible 110, which is supported by a susceptor 100. The susceptor 100 is in turn supported by a vertically moveable and rotatable shaft assembly 16. A cylindrical heater 18 made of, for example, graphite is disposed around the susceptor 100, which in turn is surrounded by an insulating cylinder 20. The bottom chamber 12 also has a conduit 40 for evacuating air during start up, and process gas during crystal pulling operations utilizing a vacuum pump (not shown).

A top chamber 24 is disposed above the bottom chamber 12 while an isolation valve 22 is disposed there between. The top chamber 24 provides a space for accommodating a grown crystal. The isolation valve 22 functions to allow a vacuum tight separation between the top chamber 24 and the bottom chamber 12 thus enabling a grown crystal to be removed from the top chamber 24 without losing vacuum or temperature in the bottom chamber 12. The top chamber 24 has a conduit 70 that goes to a vacuum pump (not shown) that allows the top chamber to be evacuation of air and/or purge gases, so it may be rejoined with the bottom chamber 12. When the isolation valve 22 is opened, a purge gas such as argon is introduced through conduit 70, flowed through the entire growing apparatus 10, and exited through conduit 40.

A winding mechanism 26 is disposed above the top chamber 24, and includes a winding drum 28 within the winding mechanism 26. The winding mechanism 26 is rotatable around a vertical axis with respect to the top chamber 24. A wire 30 is wound onto the winding drum 28, and extends downward, the wire 30 being coaxial with the shaft assembly 16. A seed chuck 32 for holding a crystal seed 34 is attached to the lower end of wire 30.

When a single crystal is to be grown in the crystal growing apparatus 10, the isolation valve 22 is in an open position so as to allow the seed 34 to be lowered into the bottom chamber 12. Both the bottom chamber 12 and the top chamber 24 are evacuated and purged of air, and an inert gas is then flowed through the apparatus for the remainder of the growing process. A charge material, such as silicon, is placed in the crucible 110, and heated by the heater 18, thereby making a molten material 36.

The seed crystal 34 is lowered by winding drum 28 until the end of the seed crystal 34 is lowered into the molten material 36. After allowing the seed crystal 34 to reach temperature equilibrium with molten material 36, the winding drum 28 slowly begins to wind up the wire 30, thus enabling a crystal 38 to be pulled or grown. During the growing operation, the winding mechanism 26 and thus the seed crystal 34 are rotating in the opposite direction of the shaft assembly 16. An active damping module 50 is placed in the top chamber 24 near the top, so as to not interfere with growth of even very long crystals.

Turning now to FIG. 2, by knowing the length l of the wire from the pendular point to the center of gravity M, the natural frequency of vibration or pendular motion ωₙ can be calculated as
ωₙ=(g/l)^{1/2}
where g is gravitational acceleration. Critical dampening can occur when an auxiliary system, having the same natural frequency, is attached to the main system and absorbs and dissipates the energy of the system into the damper. The Critical Dampening Coefficient, C_{c}, can be calculated as
C_{c}=2 mωₙ
where m is the mass of the pendulum.

Each active damping module 50 is attached to the top chamber 24, and contains a spring 52 with a known spring constant k and a control loop dampener 54 attached to a wire interceptor 56. The control loop dampener 54 is connected to a controller 58 external to the crystal pulling apparatus 10. The controller 58 is preferably part of the control system that controls growth parameters of the pulling apparatus 10, including such features as temperature, rotation of the crucible, rotation of the wire, elevation of the crystal from the melt, etc., or may be a separate controller. During standard crystal growth, the length l and mass m are calculated from the growth parameters of the pulling apparatus 10, and are used as inputs to calculate C_{c}. As such, the control loop dampener 54 is adjusted by the controller 58 to meet the critical dampening coefficient, C_{c}, of the growing crystal throughout crystal growth. The control loop dampener 54 may be in the form of a gas-driven or a hydraulic piston, but is not limited to such. The wire interceptor 56 then extends toward the pulling wire 30 such that if the crystal 38 begins to experience vibration and orbit, the wire 30 will contact the control loop dampener 54 and transfer the pendular and vibratory energy from the wire 30 to the control loop dampener 54, thereby reducing or eliminating the pendular and vibratory motion and kinetic energy from the growing crystal 38. The wire interceptor 56 can take many shapes without deviating from the invention described herein, and may be dictated by the number of active damping modules 50 used. For example, two active damping modules could be spaced angularly by 90 degrees around the wire 30, and the wire interceptors could have hollow rings at the end with the wire 30 passing therethrough. Alternatively, one active damping module could be used with a similar ring fixture around the wire 30. Two active damping modules could be placed diametrically opposed from each other, with the with wire interceptors having “v” notches or semicircular shape at the end where the pull wire 30 contacts the interceptor 56.

Although the invention has been described with reference to specific embodiments, other embodiments of the present invention will be apparent to those skilled in the art from a consideration of this specification or practice of the invention disclosed herein. It is intended that the written description be considered in all aspects only as illustrative and not restrictive. The scope of the invention is, therefore, indicated by the appended claims rather than by the foregoing description. All changes that come within the meaning and range of the equivalence of the claims are to be embraced within their scope.

1. An apparatus for reducing orbital motion during Czochralski crystal growth in a crystal pulling machine comprising:
a bottom chamber;
a crucible within the bottom chamber, the crucible rotatable around an axial axis and containing a molten material;
a top chamber above the bottom chamber;
a winding drum mounted on the top chamber, the winding drum rotatable around the axial axis;
a flexible member wound around the winding drum and extending downward along the axial axis into the pull chambers; the flexible member supporting and pulling a crystal from the molten material;
a controller; and
at least one active damping module.

2. The apparatus of claim 1, wherein the flexible member is a wire.

3. The apparatus of claim 1, wherein the flexible member is a cable.

4. The apparatus of claim 1, wherein the at least active damping module comprises a wire interceptor, a spring, and a control loop dampener.

5. The apparatus of claim 4, wherein the control loop dampener is adjusted by the controller.

6. The apparatus of claim 5, wherein the control loop dampener is gas-driven.

7. The apparatus of claim 5, wherein the control loop dampener is hydraulic.

8. An apparatus for reducing orbital motion during Czochralski crystal growth in a crystal pulling machine, comprising:
at least one active damping module for intercepting a pull wire, the pull wire having pendular motion; and
a controller, wherein the controller calculates the natural frequency of vibration for the growing crystal and adjusts the at least one active damping module to provide critical dampening.

9. The apparatus of claim 8, wherein the active dampening module comprises a wire interceptor, a spring, and a control loop dampener.

10. The apparatus of claim 9, wherein the control loop dampener is gas-driven.

11. The apparatus of claim 9, wherein the control loop dampener is hydraulic.

12. An apparatus for reducing orbital motion during Czochralski crystal growth in a crystal pulling machine, comprising:
a means for intercepting a pull wire, the pull wire moving in a pendular motion;
a means for critically damping the pull wire; and
a means for calculating the natural frequency of vibration of the pull wire and maintaining the critically damping means in a critically damping state throughout crystal growth.
